(19) United States
(12) Patent Application Publication
(10) Pub. No.: US 2025/0327862 A1
(43) Pub. Date: Oct. 23, 2025

(54) METHOD, SYSTEM, DEVICE, AND MEDIA RELATED TO DRIFT VERIFICATION

(71) Applicant: MPI Corporation, Hsinchu County (TW)

(72) Inventors: ANDREJ RUMIANTSEV, Hsinchu County (TW); Ching-Ling Pai, Hsinchu County (TW); Lin-Lin Chih, Hsinchu County (TW)

(73) Assignee: MPI Corporation, Hsinchu County (TW)

(21) Appl. No.: 19/015,511

(22) Filed: Jan. 9, 2025

Related U.S. Application Data
(60) Provisional application No. 63/637,391, filed on Apr. 23, 2024.

(51) Int. Cl. G01R 31/319

(52) U.S. Cl. CPC G01R 31/31908; G01R 31/31905

(57) ABSTRACT

A method, a system, and a media related to system drift verification are provided. In the method, first measuring with one or more modified measurement parameters is performed, to generate a first measured result of the modified measurement parameter. Second measuring with one or more modified measurement parameters is performed in response to measuring with the modified measurement parameter, to generate a second measured result of the modified measurement parameter. The second measured result with the first measured result is compared. The modified measurement parameter is different from the original measurement parameter. A compared result of the first measured result and the second measured result is used for verifying a system drift.

### CROSS-REFERENCE TO RELATED APPLICATION

This application claims the priority benefit of U.S. provisional application Ser. No. 63/637,391, filed on Apr. 23, 2024. The entirety of the above-mentioned patent application is hereby incorporated by reference herein and made a part of this specification.

### BACKGROUND OF THE DISCLOSURE

### 1. Field of the Disclosure

The present disclosure generally relates to a testing technology, in particular, to methods, systems, devices, and media related to system drift verification.

### 2. Description of Related Art

Network analyzers are essential instruments used to characterize the behavior of electronic or semiconductor devices and components in the radio frequency (RF), microwave, or other domains. The analyzers measure S-parameters, which describe how a device under test (DUT) (i.e., the aforementioned device or component) reflects and transmits signals. To ensure measurement accuracy, the analyzers require a calibration process for the error network. After finishing the calibration process, the user is able to measure the DUT. However, after a period of measurement, a failed measurement result may come out. There are many reasons for the failed measurement result, e.g., bad contact, damaged device, operator mistake, or system drift.

In most cases, there is a relatively high possibility that the failed measurement result is usually caused by “system drift”, so the user usually wants to check “system drift” first. However, conventional drift verification techniques can be time-consuming, requiring repeated measurements at regular intervals and compensation on the measured data for the system drift. There is a need for a more efficient and automated approach to drift verification that minimizes the time and effort required while maintaining measurement accuracy.

### SUMMARY OF THE DISCLOSURE

Accordingly, the present disclosure is directed to methods, systems, devices, and media related to drift verification.

According to one or more exemplary embodiments of the disclosure, a method of system drift verification in a probe system is implemented by a controller connectable with a signal generation and analysis assembly, and the signal generation and analysis assembly is connectable with a device under test (DUT) by a probing assembly. The method includes: first measuring with at least one modified measurement parameter, to generate a first measured result of the at least one modified measurement parameter; second measuring with the at least one modified measurement parameter in response to measuring with the at least one modified measurement parameter, to generate a second measured result of the at least one modified measurement parameter; and comparing the second measured result with the first measured result. The at least one modified measurement parameter is different from at least one original measurement parameter, and the at least one original measurement parameter is preconfigured in the signal generation and analysis assembly. A compared result of the first measured result and the second measured result is used for verifying a drift.

According to one or more exemplary embodiments of the disclosure, an operating method of a probe system is adapted for a controller connectable with a signal generation and analysis assembly, and the signal generation and analysis assembly is connectable with a device under test (DUT) by a probing assembly. The operating method includes: receiving a selection operation; presenting a compared result of a first measured result and a second measured result; and providing a configured boundary to verify the compared result. First measuring with at least one modified measurement parameter is performed, and the selection operation is used to replace the at least one original measurement parameter with at least one modified measurement parameter, and the at least one modified measurement parameter is different from the at least one original measurement parameter. The at least one original measurement parameter is preconfigured in the signal generation and analysis assembly. The first measured result is generated in response to the first measuring with the at least one modified measurement parameter, and the second measured result is generated in response to the second measuring with the at least one modified measurement parameter, and the compared result of the first measured result and the second measured result is used for verifying a drift. The configured boundary is shown on a display.

According to one or more exemplary embodiments of the disclosure, a probe system that is configured to test a DUT that is located on a wafer is provided. The probe system includes system drift verification. The probe system includes a chuck, a probe assembly, a signal generation and analysis assembly, and a controller. The chuck defines a support surface configured to support the wafer that includes the DUT. The probe assembly that defines a probe tip (24) is configured to physically contact a surface of the DUT. The signal generation and analysis assembly is configured to at least one of supply a test signal to the DUT and receive a resultant signal from the DUT. The controller is connected with the signal generation and analysis assembly and programmed to perform the aforementioned method of system drift verification.

According to one or more exemplary embodiments of the disclosure, a non-transitory computer-readable storage media includes computer-readable instructions that, when executed, direct a probe system to perform the method.

According to one or more exemplary embodiments of the disclosure, a method of testing an unpackaged semiconductor device designed for use in an operational environment includes: providing a controller programmed to perform the aforementioned method of system drift verification; providing at least one probe assembly for making connection to the controller to communicates teat information and having multiple tips configured to mechanically and electrically contact the unpackaged semiconductor device to communicate signals to to from the unpackaged semiconductor device; providing circuitry including a portion of the operational environment; bringing into contact the tips and the unpackaged semiconductor device; and test the unpackaged semiconductor device with the circuitry to emulate a portion of the operational environment.

According to one or more exemplary embodiments of the disclosure, a probe system that is configured to test the DUT that is located on a wafer. The probe system includes system drift verification. The probe system includes a chuck, a probe assembly, a signal generation and analysis assembly, and a controller. The chuck defines a support surface configured to support the wafer that includes the DUT. The probe assembly that defines a probe tip (24) is configured to physically contact a surface of the DUT. The signal generation and analysis assembly is configured to at least one of supply a test signal to the DUT and receive a resultant signal from the DUT. The controller is connected with the signal generation and analysis assembly and programmed to perform: first measuring with at least one modified measurement parameter, to generate a first measured result of the at least one modified measurement parameter; second measuring with the at least one modified measurement parameter in response to measuring with the at least one modified measurement parameter, to generate a second measured result of the at least one modified measurement parameter; and comparing the second measured result with the first measured result. The at least one modified measurement parameter is different from at least one original measurement parameter, and the at least one original measurement parameter is preconfigured in the signal generation and analysis assembly. A compared result of the first measured result and the second measured result is used for verifying a drift.

According to one or more exemplary embodiments of the disclosure, a method of producing a tested semiconductor device designed for use in an operational environment includes: providing a controller programmed to perform the aforementioned method of system drift verification; providing at least one probe assembly for making connection to the controller to communicate teat information and having multiple tips configured to mechanically and electrically contact the unpackaged semiconductor device to communicate signals to or from the unpackaged semiconductor device; providing circuitry including a portion of the operational environment; bringing into contact the tip and the unpackaged semiconductor device; and testing the unpackaged semiconductor device with the circuitry to emulate a portion of the operational environment.

According to one or more exemplary embodiments of the disclosure, a tested semiconductor device includes an unpackaged semiconductor device having multiple pads configured to be mechanically and electrically contacted after performing the aforementioned method.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram that illustrates a probe system according to an exemplary embodiment of the present disclosure.

FIG. 2 is a flow chart that illustrates a method of system drift verification according to an exemplary embodiment of the present disclosure.

FIG. 3 is a schematic diagram that illustrates measurement parameters according to an exemplary embodiment of the present disclosure.

FIG. 4 is a schematic diagram that illustrates measurement parameters according to an exemplary embodiment of the present disclosure.

FIG. 5 is a schematic diagram that illustrates measurement parameters according to an exemplary embodiment of the present disclosure.

FIG. 6 is a schematic diagram that illustrates movement operation according to an exemplary embodiment of the present disclosure.

FIG. 7 is a flow chart that illustrates an operating method according to an exemplary embodiment of the present disclosure.

FIG. 8 is a flow chart that illustrates a method of testing an unpackaged semiconductor device with a testing assembly according to an exemplary embodiment of the present disclosure.

FIG. 9 is a flow chart that illustrates a method of producing a tested semiconductor device according to an exemplary embodiment of the present disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

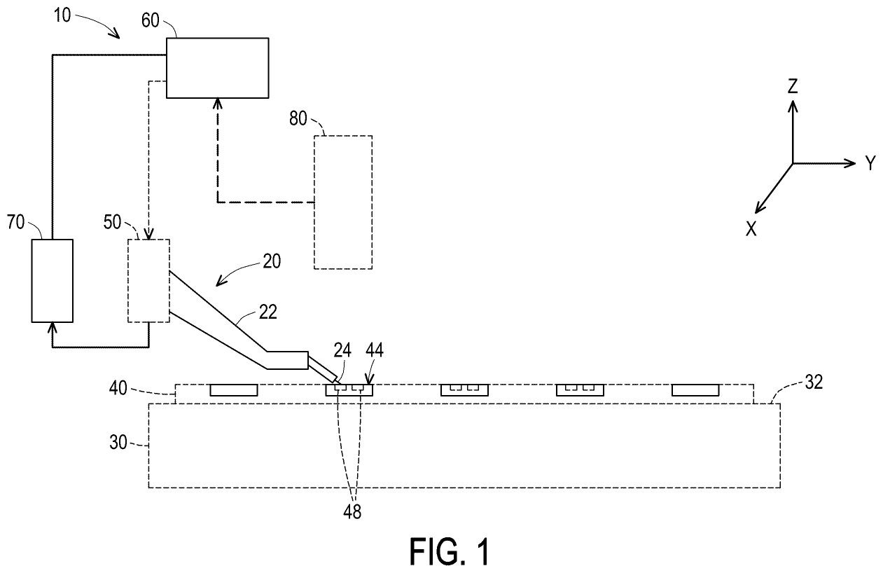

FIG. 1 is a schematic diagram that illustrates a probe system 10 according to an exemplary embodiment of the present disclosure. Referring to FIG. 1, the probe system 10 includes (but is not limited thereto) one or more probe assemblies 20, a chuck 30, a positioning assembly 50, a controller 60, a signal generation and analysis assembly 70, and an optical image device 80.

The probe assembly 20 includes (but is not limited thereto) probe 22. The probe 22 has one or more probe tips 24 for probing a device under test (DUT) 44. In one embodiment, the DUT 44 is a test semiconductor device such as a wafer, an integrated circuit (IC), or a printed circuit board (PCB). The test semiconductor device includes an unpackaged semiconductor device having one or more pads 48 configured to be mechanically and electrically contacted by the probe tip 24. In one embodiment, the DUT 44 could be a calibration standard (circuit), another electric circuit, component, or device. In one embodiment, the probe tip 24 is configured to physically contact a surface of the DUT 44.

The positioning assembly 50 may be a mechanical arm, a height adjustment table, a slide rail, a rotating table, a screw rod, or various types of combinations of mechanical components that may drive connecting components, such as the probing assembly 20 mounted thereon, to lift, lower, move or rotate, so that the probe 22 may lift, lower, move, and/or rotate. In one embodiment, the positioning assembly 50 is electrically actuated by the controller 60. For example, the controller 60 sends a command, and the positioning assembly 50 is actuated by the command to lift, lower, move or rotate the probing assembly 24 or the probe 22.

The chuck 30 has and defines a support surface 32 to allow a substrate 40 where the DUT 44 is embedded thereon to be directly placed on the chuck 30. In one embodiment, the support surface of the chuck 30 is configured to support the wafer that includes the DUT 44.

The controller 60 (e.g., having processing circuitry) may be a hardware device or circuit, e.g., a computer, a workstation, a tablet, a smartphone, a server, a wearable device, an intelligent assist device, a central processing unit (CPU), a microcontroller, a programmable controller, an application-specific integrated circuit (ASIC), a chip or other similar components or a combination of the above components. The controller 60 may call and run one or more program codes or computer-readable instructions from memory (not shown) to implement the method in the embodiment of the disclosure.

In one embodiment, the probe assembly 20 is used for making connection to the controller 60 to communicate test information.

In one embodiment, the memory may include computer-readable storage media in the form of volatile or non-volatile memory. The memory may be removable, non-removable, or a combination thereof. Exemplary memory includes solid-state memory, hard drives, optical disc drives, etc. The controller 60 may call and run one or more program codes or computer-readable instructions from the memory to implement the method in the embodiment of the disclosure.

The signal generation and analysis assembly 70 is connected with the probing assembly 20 and the controller 60. The signal generation and analysis assembly 70 may be a vector network analyzer (VNA), or other instruments for verifying parameters such as scattering parameters (S parameters), admittance parameters (Y parameters), mixing parameters (h parameters/g parameters), transmission parameters (ABCD parameters), impedance parameters (Z parameters), or scattering transmission parameters (T Parameters). The signal generation and analysis assembly 70 is connectable with the DUT 44 by cable or connector via one or more probing assemblies 20. In one embodiment, the signal generation and analysis assembly 70 is configured to send test signals and receive measured signals via one or more probes 22.

In one embodiment, the controller 60 may send one or more commands or instructions to the signal generation and analysis assembly 70, and the commands or instructions are related to actuating or triggering one or more functions of the signal generation and analysis assembly 70 and/or sending one or more parameters to configure the signal generation and analysis assembly 70. In one embodiment, the commands or instructions are implemented by running or executing corresponding program codes or computer-readable instructions.

The optical image device 80 may be an optical inspection device. The optical image device 80 is configured to collect an optical image of one or more regions of the probe system 10. In one embodiment, the optical image device 80 is configured to detect defects on the DUT 44. The optical image device 80 may use various optical techniques to identify a wide range of defects that can affect the functionality and performance of the DUT 44.

The circuitry can also be organized such that, in concert with the DUT 44, a full system is created for evaluating the DUT 44. For example, the probe system 10 could include support circuits for a personal computer motherboard if the DUT 44 is a microprocessor. On power up, the DUT 44 will experience an electrical environment like the final use environment. In this way, a test of system drift can be performed on unpackaged DUT devices. Use of the probe system with such programmable modes allows self test to be performed in the wafer production test environment.

For ease of understanding of the operation process of the embodiments of the disclosure, several embodiments will be provided below to describe the flow of the use of the probe system 10 in the embodiment of the disclosure. Hereinafter, the method described in the embodiments of the disclosure will be described together with each of the devices, components, and modules in the probe system 10. Each of the flows of the method may be adjusted according to actual implementation scenarios, and the disclosure is not limited thereto.

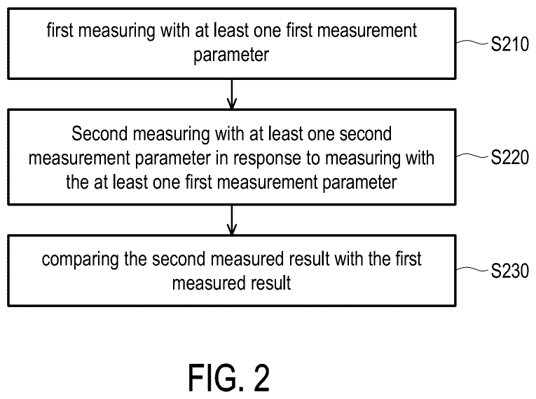

FIG. 2 is a flow chart that illustrates a drift verifying method according to an exemplary embodiment of the present disclosure. Referring to FIG. 2, the controller 60 first-measures, through the signal generation and analysis assembly 70 via the probe assembly 20, with at least one modified measurement parameter, to generate a first measured result of the at least one modified measurement parameter (step S210). Specifically, the probe assembly 20 may contact the DUT for the measurement with the modified measurement parameter. Alternatively, the measurement with the modified measurement parameter may be performed over-the-air (OTA). The measurement in step S210 is a baseline measurement, which serves as a reference or a golden sample for future or subsequent measurements. The type of the modified measurement parameter may include any one of or a combination of a frequency range, the start frequency of the frequency range, the stop frequency of the frequency range, frequency points, the amount/number of the frequency points, and enabling or disabling of correction for the drift. The frequency points are located within the frequency range. That is, the frequency of the frequency point is not less than the start frequency and is not larger than the stop frequency. The first measured result of the modified measurement parameter may be, for example, one or more S-parameters. In one embodiment, the first measured result may be stored as a drift reference dataset. The drift reference dataset may further include the modified measurement parameter.

However, the at least one modified measurement parameter is different from at least one original measurement parameter. One or more original measurement parameters are preconfigured in the signal generation and analysis assembly 70. That is the original measurement parameters are the default measurement parameters for signal generation and analysis assembly 70.

In one embodiment, the controller 60 may measure with one or more original measurement parameters in a calibration process of the signal generation and analysis assembly 70. The calibration process is used to remove errors in the VNA, cables, connectors, and/or adapters. This may ensure that the measurement with the original measurement parameter has no errors. That is, after the calibration process, the original measurement parameter would be preconfigured in the signal generation and analysis assembly 70. In the calibration process, the DUT 44 may be one or more calibration standards (circuits). The typical calibration kit includes Short, Open, Load, and Throuh (Thru). The calibration methods may be SOLT (Short-Open-Load-Through) or TRL (Thru-Reflect-Line). The controller 60 or the signal generation and analysis assembly 70 may detect the termination of the calibration process, and the measure with one or more modified measurement parameters is performed in response to the termination of the calibration process. That is one or some measurement parameters used in the measurement of step S210 are different from the one or some measurement parameter configured in the signal generation and analysis assembly 70 after the calibration process which is the process before the measurement of step S210.

Referring to FIG. 2, the controller 60 second-measures, through the signal generation and analysis assembly 70 via the probe assembly 20, with the at least one modified measurement parameter in response to measuring with the at least one modified measurement parameter, to generate a second measured result of the at least one modified measurement parameter (step S220). Specifically, the probe assembly 20 may contact the same DUT as the DUT used in the measurement with the same modified measurement parameter for the measurement in step S210. Alternatively, the measurement with the same modified measurement parameter may be performed over-the-air (OTA) as the same as the measurement in step S210. After step S210, the system drift may exist, and the same modified measurement parameters would be used for the drift verification. The second measured result of the modified measurement parameter may be, for example, one or more S-parameters. In one embodiment, the second measured result may be stored as a drift dataset. The drift dataset may further include the modified measurement parameter.

In the first embodiment, the modified measurement parameter may include a disabling of correction for the system drift verification, and the original measurement parameter may include an enabling of the correction for the system drift verification. Factors like temperature changes, component aging, and mechanical disturbances may cause performance variations. These performance variations can lead to measurement drift (known as system drift or drift), affecting the accuracy and reliability of measurements. The signal generation and analysis assembly 70 provides a correction function for the drift. The controller 60 may calculate mathematical corrections to the measured data of the signal generation and analysis assembly 70, to generate error terms or compensation data for the compensation of the drift. The correction function would use error terms or compensation data to correct the measured data, such that the corrected data corresponding to the measured data would be obtained. The enabling of the correction for the drift is that the correction function of the signal generation and analysis assembly 70 would be applied, actuated, or triggered in response to the detection of the drift. On the other hand, the disabling of the correction for the drift is that the correction function of the signal generation and analysis assembly 70 is terminated, disabled, forbidden, or blocked and would not be applied, actuated, or triggered in response to the detection of the drift.

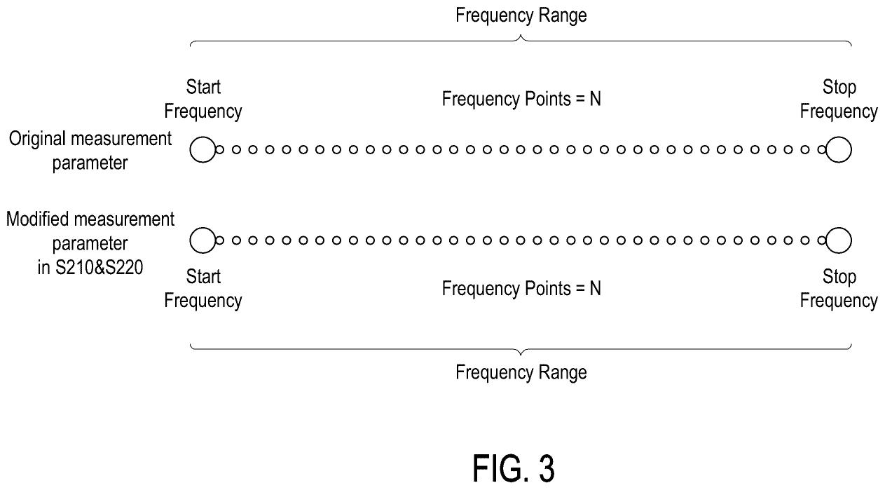

Except for the disabling of the correction for the drift, the values of other types of measurement parameters used in step S210 and step S220 may be the same as the values of other types of original measurement parameters. For example, FIG. 3 is a schematic diagram that illustrates measurement parameters according to an exemplary embodiment of the present disclosure. Referring to FIG. 3, the frequency range from the start frequency to the stop frequency used in step S210 and step S220 is the same as the frequency range from the start frequency to the stop frequency used in the original measurement parameters. The frequency points and the amount/number of the frequency points (e.g., N which is a positive integer) used in step S210 and step S220 are the same as the frequency points and the amount/number of the frequency points (e.g., N which is a positive integer) used in the original measurement parameters. However, because of the disabling of the correction of the system drift verification, a certain amount of sweep number would be reduced relative to the enabling of the correction of the system drift verification. For example, the signal generation and analysis assembly 70 may apply a 2-port error correction algorithm even on the one-port dataset. When the user wants to measure just S11 after the two-port calibration, the signal generation and analysis assembly 70 needs to measure all raw S-parameters to complete one corrected S11. This is how the correction function works, and all four S-parameters should be measured even if the user needs only S11. If the disabling of the correction of the system drift verification is applied, the measuring time in step S210 and step S220 would be reduced by taking less measurement sweep number relative to the enabling of the correction of the system drift verification.

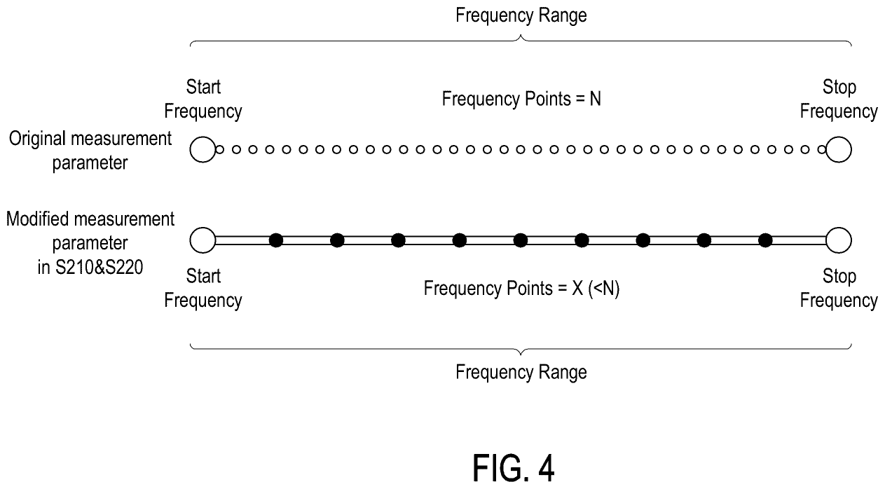

In the second embodiment, the modified measurement parameter includes one or more frequency points for measuring in which the amount/number of the frequency points of the modified measurement parameter is less than the amount/number of frequency points of the original measurement parameter. For example, FIG. 4 is a schematic diagram that illustrates measurement parameters according to an exemplary embodiment of the present disclosure. Referring to FIG. 4, the amount/number of the frequency points (e.g., X which is a positive integer less than N which is a positive integer) used in step S210 and step S220 is less than the amount/number of the frequency points (e.g., N which is a positive integer) used in the original measurement parameters. Also, one or some of the frequency points used in step S210 and step S220 may be different from one or some of the frequency points used in the original measurement parameters. Except for the frequency points, the frequency range from the start frequency to the stop frequency used in step S210 and step S220 is the same as the frequency range from the start frequency to the stop frequency used in the original measurement parameters. Furthermore, the enabling of the correction of the system drift verification is applied in step S210 and step S220. However, because of fewer frequency points, the measuring time would be reduced.

In the third embodiment, the modified measurement parameter may include a disabling of correction for a drift, and the original measurement parameter may include an enabling of the correction for the drift. Furthermore, the modified measurement parameter further includes one or more frequency points for measuring in which the amount/number of the frequency points of the modified measurement parameter is less than the amount/number of frequency points of the original measurement parameter. For example, FIG. 4 is a schematic diagram that illustrates measurement parameters according to an exemplary embodiment of the present disclosure. Referring to FIG. 4, the amount/number of the frequency points (e.g., X which is a positive integer less than N which is a positive integer) used in step S210 and step S220 is less than the amount/number of the frequency points (e.g., N which is a positive integer) used in the original measurement parameters. Also, one or some of the frequency points used in step S210 and step S220 may be different from one or some of the frequency points used in the original measurement parameters. Except for the frequency points, the frequency range from the start frequency to the stop frequency used in step S210 and step S220 is the same as the frequency range from the start frequency to the stop frequency used in the original measurement parameters. Furthermore, the disabling of the correction of the system drift verification is applied in step S210 and step S220. However, because of fewer frequency points and the disabling of the correction of the system drift verification, the measuring time would be reduced.

In the fourth embodiment, the modified measurement parameter may include a disabling of correction for a drift, and the original measurement parameter may include an enabling of the correction for the drift. The modified measurement parameter further includes one or more frequency points for measuring in which the amount/number of the frequency points of the modified measurement parameter is less than the amount/number of frequency points of the original measurement parameter. Furthermore, the modified measurement parameter further includes the first frequency range for measuring in which the first frequency range is less than the second frequency range of the original measurement parameter.

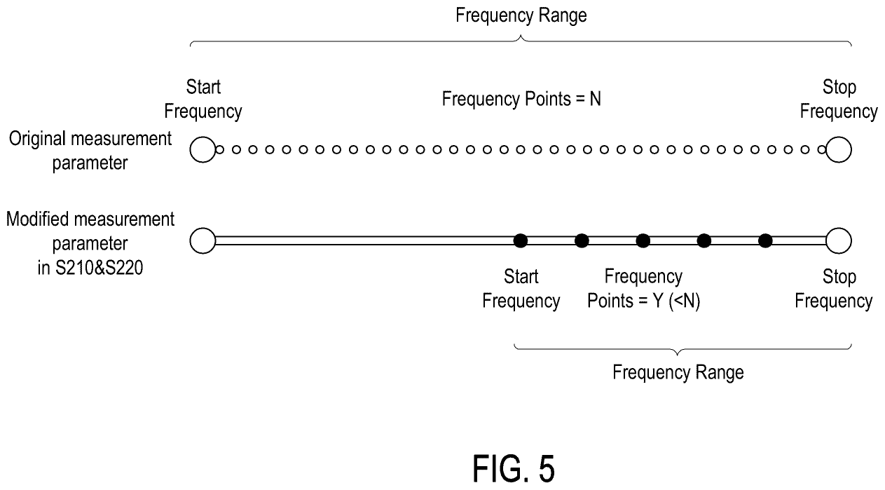

For example, FIG. 5 is a schematic diagram that illustrates measurement parameters according to an exemplary embodiment of the present disclosure. Referring to FIG. 5, the frequency range of the measurement parameters used in step S210 and step S220 (i.e., the first frequency range) is different from the frequency range of the original measurement parameters (i.e., the second frequency range). The start frequency of the frequency range of the measurement parameters used in step S210 and step S220 is different from the start frequency of the frequency range of the original measurement parameters, and the stop frequency of the frequency range of the measurement parameters used in step S210 and step S220 is different from the stop frequency of the frequency range of the original measurement parameters. Furthermore, the amount/number of the frequency points (e.g., Y which is a positive integer less than N which is a positive integer) used in step S210 and step S220 is less than the amount/number of the frequency points (e.g., N which is a positive integer) used in the original measurement parameters. Also, one or some of the frequency points used in step S210 and step S220 may be different from one or some of the frequency points used in the original measurement parameters. Furthermore, the disabling of the correction of the system drift verification is applied in step S210 and step S220. Because of the smaller frequency range, fewer frequency points, and the disabling of the correction of the system drift verification, the measuring time would be reduced.

In one embodiment, the controller 60 may copy a parameter set. The parameter set includes one or more original measurement parameters of the signal generation and analysis assembly 70. For example, the parameter set includes any one of or a combination of a frequency range, the start frequency of the frequency range, the stop frequency of the frequency range, frequency points, the amount/number of the frequency points, and enabling or disabling of correction for the drift. The controller 60 may replace the original measurement parameter in the parameter set with the at least one modified measurement parameter, to generate a new parameter set including the modified measurement parameter. Taking an example for the second or third embodiment, one or more frequency points would be replaced. Taking an example for the fourth embodiment, the start frequency or the stop frequency would be replaced. Then, the controller 60 may send the new parameter set to the signal generation and analysis assembly 70. Therefore, the signal generation and analysis assembly 70 may perform the measurement with the modified measurement parameter.

In one embodiment, the sweep number of measuring with the at least one modified measurement parameter is reduced relative to the sweep number of measuring with the at least one original measurement parameter. By disabling of correction for the drift, reducing the amount of the frequency points, and/or reducing the frequency range, the sweep number of measurements would be reduced.

Referring to FIG. 2, the controller 60 compares the second measured result with the first measured result (step S230). Specifically, the compared result of the first measured result and the second measured result is used for verifying a drift. The controller 60 may check the difference between the first measured result and the second measured result. The compared result may be the magnitude difference between the first measured result and the second measured result. The controller 60 may configure boundaries or thresholds for the difference, to verify whether the system drifted. For example, if the magnitude difference is within the configured boundary, the controller 60 would determine the drift or the system drift exists or is detected. If the magnitude difference is not within the configured boundary, the controller 60 would determine the drift or the system drift does not exist or is not detected. In one embodiment, the absolute value of the measured result is used for determining the correctness of the first and second measured results. If the first measured result is wrong, the magnitude difference would not be used for comparison with the configured boundary.

It should be noticed that in response to the detecting of the system drift, the signal generation and analysis assembly 70 would perform the correction function because of the enabling of the correction of the system drift verification. However, in response to the detecting of the system drift, the signal generation and analysis assembly 70 would not perform the correction function because of the disabling of the correction of the system drift verification.

In the fifth embodiment, the controller 60 may send a movement command of the probing assembly 20 to the positioning assembly 50. The movement command may be a command related to lifting, lowering, or moving a designed distance and/or rotating a designed degree. The positioning assembly 50 would lift, lower, move, and/or rotate the probing assembly 20 according to the movement command. In one embodiment, the controller 60 may send a movement command of the chuck 30 to the chuck translation structure. The chuck translation structure would lift, lower, move, and/or rotate the chuck 30 according to the movement command. The chuck translation structure includes an actuator, an electric actuator, a stepper motor, a piezoelectric actuator, a rack and pinion assembly, a ball screw and nut assembly, a linear actuator, a linear motor, and/or a rotary actuator.

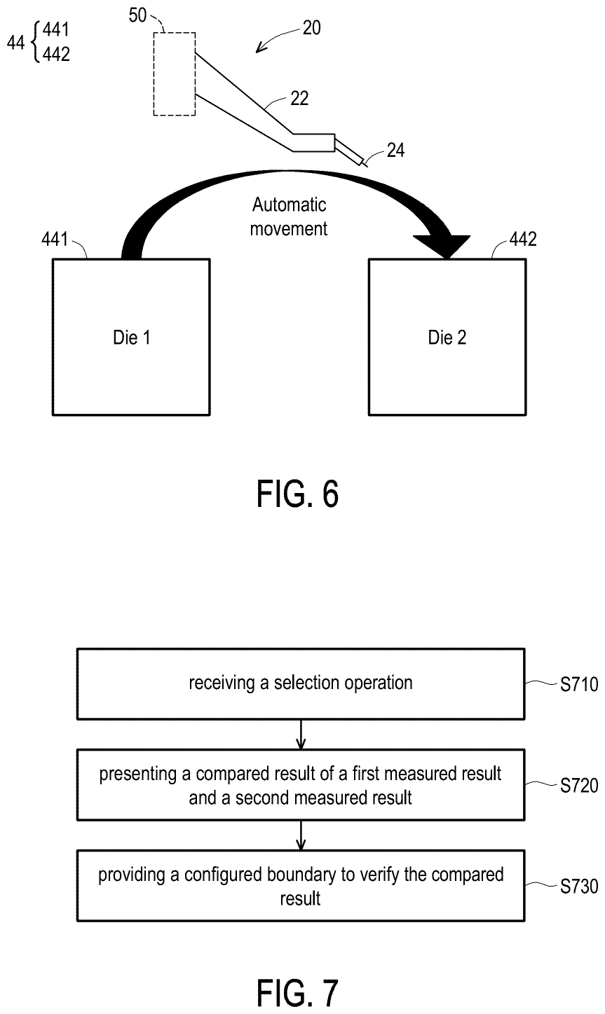

For example, FIG. 6 is a schematic diagram that illustrates movement operation according to an exemplary embodiment of the present disclosure. Referring to FIG. 6, the DUT 44 may be the first die 441 and the second die 442. The movement command is used to move the probing assembly 20 from the location where the probe tip 24 contact the first die 441 to the location where the probe tip 24 contact the second die 442.

It should be noticed that the movement of the probing assembly 20 is performed in response to the measuring with the modified measurement parameter. For example, the measuring with the modified measurement parameter is performed in response to the movement command being sent. The drift verification would be performed while the probe 22 is raised in the air. Therefore, the movement time gap is used to check the system drift, so as to save time. In one embodiment, the modified measurement parameter of the first, second, third, or fourth embodiment is applied during the movement of the probing assembly 20.

FIG. 7 is a flow chart that illustrates an operating method of a probe system 10 according to an exemplary embodiment of the present disclosure. Referring to FIG. 7, the controller 60 receives a selection operation (step S710). Specifically, measuring with the modified measurement parameter is performed as mentioned in step S210. The selection operation is used to replace the original measurement parameter with the modified measurement parameter, and the modified measurement parameter is different from the original measurement parameter. As mentioned above, the configuration of the correction of the system drift verification, the frequency range, the start frequency, the stop frequency, or the frequency point of the modified measurement parameter is different from the original measurement parameter, and the original measurement parameter is preconfigured in the signal generation and analysis assembly 70. The controller 60 may provide verification options related to the aforementioned first, second, third, fourth, and/or fifth embodiment on a user interface. By referring to the description of the aforementioned first, second, third, fourth, and/or fifth embodiment, the introduction of the modified measurement parameter for the first, second, third, fourth, and/or fifth embodiment would be omitted.

An input device (not shown, for example, a keyboard, a mouse, or a touch panel) receives the selection operation for one of the verification options on the user interface. The selection operation may further include the selection of the value of the modified measurement parameter. For example, the stat frequency, the stop frequency, or the frequency points.

Then, the measurement with the modified measurement parameter is performed as mentioned in step S210 and step S220 based on the selection operation.

The controller 60 presents a compared result of a first measured result and a second measured result (step S720). Specifically, the first measured result is generated in response to the measuring with the modified measurement parameter, and the second measured result is generated in response to the measuring with the modified measurement parameter. Furthermore, the compared result of the first measured result and the second measured result is used for verifying a system drift. For example, the magnitude difference between the first measured result and the second measured result would be presented, or the detection of the system drift would be presented. In one embodiment, a display or a speaker (not shown) may be used to present the compared result of the first measured result and the second measured result.

The controller 60 provides a configured boundary to verify the compared result (step S730). Specifically, the configured boundary is shown on a display. As mentioned above, the configured boundary could be used to verify whether the system drifted. For example, the compared result is the magnitude difference between the first measured result and the second measured result, and the system drift is detected if the magnitude difference is within the configured boundary. Furthermore, the compared result and the configured boundary could be shown on the display together, so that the user would see the verification result of the system drift.

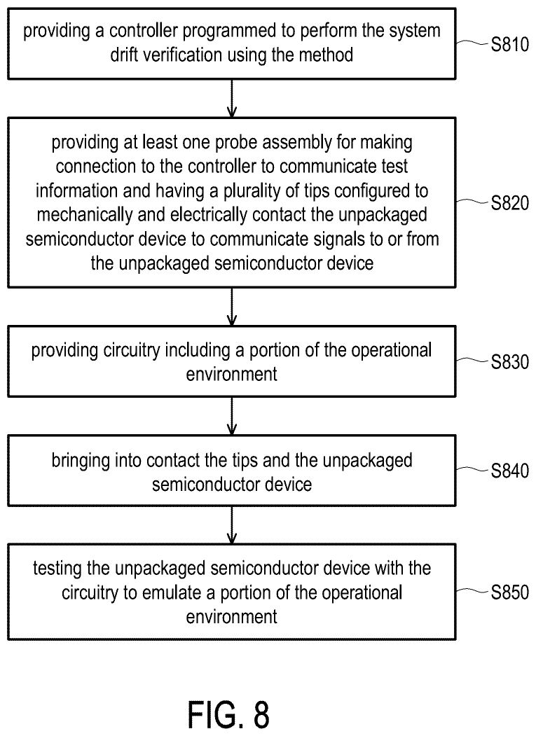

FIG. 8 is a flow chart that illustrates a method of testing an unpackaged semiconductor device designed for use in an operational environment according to an exemplary embodiment of the present disclosure. Referring to FIG. 8, a controller 60 programmed to perform the method of the aforementioned embodiments is provided (step S810). Specifically, the controller 60 measures with at least one modified measurement parameter, to generate a first measured result of the at least one modified measurement parameter. The controller 60 measures with at least one modified measurement parameter in response to measuring with the at least one modified measurement parameter, to generate a second measured result of the at least one modified measurement parameter. The modified measurement parameter is different from the original measurement parameter, and the original measurement parameter is preconfigured in the signal generation and analysis assembly 70. The controller 60 compares the second measured result with the first measured result. The compared result of the first measured result and the second measured result is used for verifying a system drift.

One or more probe assembly 20 is provided (step S820) for making connection to the controller 60 to communicate test information and having one more probe tips 24 configured to mechanically and electrically contact an unpackaged semiconductor device 44 to communicate signals to or from the unpackaged semiconductor device 44 (i.e., the DUT 44). The unpackaged semiconductor device may be tested during step S210, step S220, or after the drift verification. A circuitry including a portion of the operational environment is provided (step S830).

The circuitry includes one or more elements in the probe system 10 on one or more circuit board. When the probe system 10 operates, the operational environment is initiated.

The probe system 10 is brought into contact the probe tips 24 and the unpackaged semiconductor device (step S840). Then, the unpackaged semiconductor device is tested with the circuitry to emulate a portion of the operational environment.

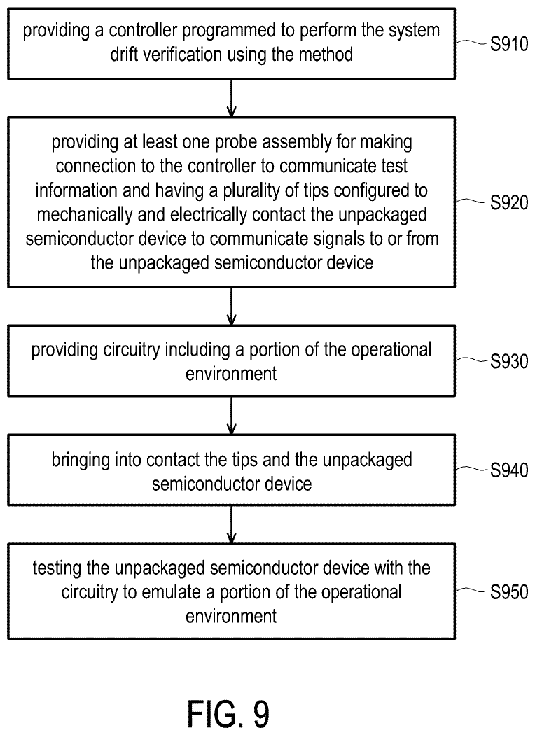

FIG. 9 is a flow chart that illustrates a method of producing a tested semiconductor device designed for use in an operational environment according to an exemplary embodiment of the present disclosure. Referring to FIG. 9, a controller 60 programmed to perform the method of the aforementioned embodiments is provided (step S910). Specifically, the controller 60 measures with at least one modified measurement parameter, to generate a first measured result of the at least one modified measurement parameter. The controller 60 measures with at least one modified measurement parameter in response to measuring with the at least one modified measurement parameter, to generate a second measured result of the at least one modified measurement parameter. The modified measurement parameter is different from the original measurement parameter, and the original measurement parameter is preconfigured in the signal generation and analysis assembly 70. The controller 60 compares the second measured result with the first measured result. The compared result of the first measured result and the second measured result is used for verifying a system drift.

One or more probe assembly 20 is provided (step S920) for making connection to the controller 60 to communicate test information and having one more probe tips 24 configured to mechanically and electrically contact an unpackaged semiconductor device 44 to communicate signals to or from the unpackaged semiconductor device 44 (i.e., the DUT 44). The unpackaged semiconductor device may be tested during step S210, step S220, or after the drift verification.

A circuitry including a portion of the operational environment is provided (step S930). The circuitry includes one or more elements in the probe system 10 on one or more circuit board. When the probe system 10 operates, the operational environment is initiated.

The probe system 10 is brought into contact the probe tips 24 and the unpackaged semiconductor device (step S940). Then, the unpackaged semiconductor device is tested with the circuitry to emulate a portion of the operational environment.

The implementation details of some of the steps in FIG. 7, FIG. 8, and FIG. 9 are described in detail in the foregoing embodiments and implementation method. Thus, details in this regard will not be further reiterated in the following. In addition to being implemented in the form of a circuit, the steps and implementation details in the embodiment of the disclosure may also be implemented in the form of software by a processing unit. The embodiment of the disclosure is not limited thereto.

Reference is made to FIG. 1 to FIG. 9. Based on the above description, the present disclosure also provides a non-transitory computer-readable storage media. The non-transitory computer-readable storage media includes one or more computer-executable instructions. The computer-executable instructions are able to direct a probe system 10 for performing the method of any one of the embodiments described above. A computer-readable storage media, when present, may also be referred to as the non-transitory computer readable storage media herein. This non-transitory computer readable storage media may include, define, house, and/or store computer-executable instructions, programs, and/or codes. These computer-executable instructions may direct the probe system 10 and/or the controller 60 thereof to perform any suitable portion or subset of the methods of above embodiment. Examples of such non-transitory computer-readable storage media include CD-ROMs, disks, hard drives, flash memory, etc.

Based on the above, the methods, systems, devices, and media related to drift verification provided by the embodiments of the disclosure replace the measurement parameter such as disabling of correction of the system drift verification, start frequency, stop frequency, or frequency points for less sweep number, fewer frequency points, or using the movement time gap. In this way, the embodiments of the disclosure may effectively reduce the measuring time of drift verification and further improve the efficiency of the test process.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A method of system drift verification in a probe system, implemented by a controller (60) connectable with a signal generation and analysis assembly (70), the signal generation and analysis assembly (70) being connectable with a device under test (DUT) (44) by a probing assembly (20), and the method comprising:
first measuring with at least one modified measurement parameter, to generate a first measured result of the at least one modified measurement parameter, wherein the at least one modified measurement parameter is different from at least one original measurement parameter, and the at least one original measurement parameter is preconfigured in the signal generation and analysis assembly (70);
second measuring with the at least one modified measurement parameter in response to measuring with the at least one modified measurement parameter, to generate a second measured result of the at least one modified measurement parameter; and
comparing the second measured result with the first measured result, wherein a compared result of the first measured result and the second measured result is used for verifying a system drift.

2. The method according to claim 1, wherein the at least one modified measurement parameter comprises a disabling of correction for the system drift verification, and the at least one original measurement parameter comprises an enabling of the correction for the system drift verification.

3. The method according to claim 2, wherein the at least one modified measurement parameter further comprises at least one frequency point for measuring in which an amount of the at least one frequency point of the at least one modified measurement parameter is less than an amount of frequency points of the at least one original measurement parameter.

4. The method according to claim 2, wherein the at least one modified measurement parameter further comprises a first frequency range for measuring in which the first frequency range is less than a second frequency range of the at least one original measurement parameter.

5. The method according to claim 1, wherein the at least one modified measurement parameter comprises at least one frequency point for measuring in which an amount of the at least one frequency point of the at least one modified measurement parameter is less than an amount of frequency points of the at least one original measurement parameter.

6. The method according to claim 1, further comprising:
sending a movement command of the probing assembly (20), wherein a movement of the probing assembly (20) is performed according to the movement command in response to the measuring with at least one modified measurement parameter.

7. The method according to claim 1, wherein the first or second measuring with the at least one modified measurement parameter comprises:
copying a parameter set, wherein the parameter set comprising the at least one original measurement parameter of the signal generation and analysis assembly (70);
replacing the measurement parameters in the parameter set with the at least one modified measurement parameter, to generating a new parameter set comprising the at least one modified measurement parameter; and
sending the new parameter set.

8. The method according to claim 1, wherein the compared result of the first measured result and the second measured result is a magnitude difference between the first measured result and the second measured result, and comparing the second measured result with the first measured result comprises:
determining the system drift is detected in response to the magnitude difference being within a configured boundary; and
determining the system drift is not detected in response to the magnitude difference being not within the configured boundary.

9. The method according to claim 1, wherein a sweep number of measuring with the at least one modified measurement parameter is reduced relative to a sweep number of measuring with the at least one original measurement parameter.

10. An operating method of a probe system (10), adapted for a controller (60) connectable with a signal generation and analysis assembly (70), the signal generation and analysis assembly (70) being connectable with a device under test (DUT) (44) by a probing assembly (20), and the operating method comprising:
receiving a selection operation, wherein measuring with at least one modified measurement parameter is performed, the selection operation is used to replace at least one original measurement parameter with at least one modified measurement parameter, the at least one modified measurement parameter is different from the at least one original measurement parameter, and the at least one original measurement parameter is preconfigured in the signal generation and analysis assembly (70);
presenting a compared result of a first measured result and a second measured result, wherein the first measured result is generated in response to first measuring with the at least one modified measurement parameter, the second measured result is generated in response to second measuring with the at least one modified measurement parameter, and the compared result of the first measured result and the second measured result is used for verifying a system drift; and
providing a configured boundary to verify the compared result, wherein the configured boundary is shown on a display.

11. The operating method according to claim 10, wherein the at least one modified measurement parameter comprises a disabling of correction for the system drift verification, and the at least one original measurement parameter comprises an enabling of the correction for the system drift verification.

12. The operating method according to claim 10, wherein
the at least one modified measurement parameter further comprises at least one frequency point for measuring in which an amount of the at least one frequency point of the at least one modified measurement parameter is less than an amount of frequency points of the at least one original measurement parameter; or
the at least one modified measurement parameter further comprises a first frequency range for measuring in which the first frequency range is less than a second frequency range of the at least one original measurement parameter.

13. The operating method according to claim 10, wherein the at least one modified measurement parameter comprises at least one frequency point for measuring in which an amount of the at least one frequency point of the at least one modified measurement parameter is less than an amount of frequency points of the at least one original measurement parameter.

14. The operating method according to claim 10, further comprising:
sending a movement command of the probing assembly (20), wherein a movement of the probing assembly (20) is performed according to the movement command in response to the measuring with at least one modified measurement parameter.

15. A probe system (10) that is configured to test a device under test (DUT) (44) that is located on a wafer, the probe system (10) including system drift verification and comprising:
a chuck (30) that defines a support surface configured to support the wafer that includes the device under test (DUT) (44);
a probe assembly (20) that defines a probe tip (24) configured to physically contact a surface of the DUT (44);
a signal generation and analysis assembly (70), configured to at least one of supply a test signal to the DUT (44) and receive a resultant signal from the DUT (44); and
a controller (60), connected with the signal generation and analysis assembly (70), and programmed to perform the method of claim 1.

16. The probe system (10) according to claim 15, wherein the probe system (10) further includes:
a positioning assembly (50) configured to selectively vary a relative orientation between the probe tip (24) and the chuck (30); and
a optical image device (80) configured to collect an optical image of at least a region of the probe system (10);
wherein the signal generation and analysis assembly (70) is a network analyzer (70).

17. A non-transitory computer-readable storage media, comprising computer-readable instructions that, when executed, direct a probe system (10) to perform the method of claim 1.

18. A method of testing an unpackaged semiconductor device (44), the unpackaged semiconductor device (44) designed for use in an operational environment, the method comprising:
providing a controller (60) programmed to perform the system drift verification using the method of claim 1;
providing at least one probe assembly (20) for making connection to the controller (60) to communicate test information and having a plurality of tips (24) configured to mechanically and electrically contact an unpackaged semiconductor device (44) to communicate signals to or from the unpackaged semiconductor device (44);
providing circuitry including a portion of the operational environment;
bringing into contact the tips (24) and the unpackaged semiconductor device (44); and
testing the unpackaged semiconductor device (44) with the circuitry to emulate a portion of the operational environment.

19. A method of producing a tested semiconductor device (44), the tested semiconductor device (44) designed for use in an operational environment, the method comprising:
providing a controller (60) programmed to perform the system drift verification using the method of claim 1;
providing at least one probe assembly (20) for making connection to the controller to communicate test information and having a plurality of tips (24) configured to mechanically and electrically contact an unpackaged semiconductor device (44) to communicate signals to or from the unpackaged semiconductor device (44);
providing circuitry including a portion of the operational environment;
bringing into contact the tips (24) and the unpackaged semiconductor device (44); and
testing the unpackaged semiconductor device (44) with the circuitry to emulate a portion of the operational environment.

20. A tested semiconductor device (44), comprising:
an unpackaged semiconductor device (44) having a plurality of pads (48) configured to be mechanically and electrically contacted after performing the method of claim 1.
